(19) United States
(12) Patent Application Publication
(10) Pub. No.: US 2025/0324860 A1
(43) Pub. Date: Oct. 16, 2025

(54) DISPLAY DEVICE AND MOBILE ELECTRONIC DEVICE INCLUDING SAME

(71) Applicant: Samsung Display Co., Ltd., Yongin-si (KR)

(72) Inventors: Yoon A KIM, Yongin-si (KR); Ok Kyung PARK, Yongin-si (KR); Jeong Yoon LEE, Yongin-si (KR); Dae Young JOUNG, Yongin-si (KR); Young Cheol JEONG, Yongin-si (KR)

(21) Appl. No.: 19/174,780

(22) Filed: Apr. 9, 2025

(30) Foreign Application Priority Data
Apr. 16, 2024 (KR) 10-2024-0050741

(51) Int. Cl. H10K 59/122; H10K 59/131

(52) U.S. Cl. CPC H10K 59/122; H10K 59/131

(57) ABSTRACT

A display device and a mobile electronic device including the same are provided. A display device including: a substrate; and a display element layer on the substrate, wherein the display element layer includes: a pixel defining film delimiting a plurality of sub-pixels; a first electrode of each of the plurality of sub-pixels located in an opening of the pixel defining film; a first wiring on the pixel defining film between the neighboring sub-pixels; a light-emitting stack on the first electrode and the pixel defining film comprising the first wiring, and disconnected around the first wiring; and a second electrode on the light-emitting stack, wherein a top surface of the pixel defining film around the first wiring is not flat and has a cross-sectional shape of a first pattern, and a top surface of the first wiring is not flat and has a cross-sectional shape of a second pattern.

### CROSS-REFERENCE TO RELATED APPLICATION

This application claims priority to and the benefit of Korean Patent Application No. 10-2024-0050741, filed on Apr. 16, 2024, in the Korean Intellectual Property Office, the entire disclosure of which is incorporated by reference herein.

### BACKGROUND

### 1. Field

The present disclosure relates to a display device and a mobile electronic device including the same.

### 2. Description of the Related Art

Wearable devices in which a focus is formed at a distance close to user's eyes have been developed in the form of glasses or a helmet. For example, the wearable device may be a head mounted display (HMD) device and/or augmented reality (AR) glasses. The wearable device provides an augmented reality (hereinafter, referred to as “AR”) screen or a virtual reality (hereinafter, referred to as “VR”) screen to a user.

The wearable devices such as the HMD device and/or the AR glasses require a display specification of at least 2000 PPI (pixels per inch) so that a user may use it for a long time without dizziness. To this end, organic light-emitting diode on silicon (OLEDoS) technology that is a high-resolution small organic light-emitting display device is emerging. The organic light-emitting diode on silicon (OLEDoS) is technology for disposing an organic light-emitting diode (OLED) on a semiconductor wafer substrate on which a complementary metal oxide semiconductor (CMOS) is disposed.

In a display panel to which the OLEDoS technology is applied, an unintended leakage current may occur between neighboring sub-pixels as the distance between the neighboring sub-pixels decreases. The leakage current may occur through some conductive layers in a light-emitting stack disposed between a pixel electrode (for example, anode electrode) and a common electrode (for example, cathode electrode), and is known as a cause of color crosstalk between adjacent sub-pixels.

### SUMMARY

Aspects and features of embodiments of the present disclosure provide a display device capable of reducing and/or preventing leakage current and color crosstalk by disconnecting a light-emitting stack between neighboring sub-pixels, and also provide a mobile electronic device including the same.

According to one or more embodiments of the present disclosure, a display device including: a substrate; and a display element layer on the substrate, wherein the display element layer includes: a pixel defining film delimiting a plurality of sub-pixels; a first electrode of each of the plurality of sub-pixels located in an opening of the pixel defining film; a first wiring on the pixel defining film between the neighboring sub-pixels; a light-emitting stack on the first electrode and the pixel defining film comprising the first wiring, and disconnected around the first wiring; and a second electrode on the light-emitting stack, wherein a top surface of the pixel defining film around the first wiring is not flat and has a cross-sectional shape of a first pattern, and a top surface of the first wiring is not flat and has a cross-sectional shape of a second pattern.

In one or more embodiments, the first pattern of the pixel defining film includes a trench in which the first wiring is located.

In one or more embodiments, the second pattern of the first wiring has a cross-sectional structure of a positive tapered shape.

In one or more embodiments, the second pattern of the first wiring has a triangular shape having a width that gradually narrows from a bottom surface of the trench to a top surface of the trench.

In one or more embodiments, the second pattern of the first wiring includes at least one groove at the top surface of the first wiring.

In one or more embodiments, a bottom surface of the at least one groove at the top surface of the first wiring is flat.

In one or more embodiments, a bottom surface of the at least one groove at the top surface of the first wiring is concave.

In one or more embodiments, the second pattern of the first wiring includes a plurality of circular protrusions on the top surface of the first wiring.

In one or more embodiments, the second pattern of the first wiring includes a plurality of triangular protrusions on the top surface of the first wiring.

In one or more embodiments, the second pattern of the first wiring further includes a groove between the adjacent triangular protrusions.

In one or more embodiments, the second pattern of the first wiring includes a plurality of triangular protrusions on a side surface and the top surface of the first wiring.

In one or more embodiments, the trench in the pixel defining film has a concave bottom surface.

In one or more embodiments, the first pattern of the pixel defining film includes a trench having a height lower than that of the first wiring, surrounding the first wiring, and having a concave bottom surface.

In one or more embodiments, the first pattern of the pixel defining film includes a convex top surface of the pixel defining film.

In one or more embodiments, the first pattern of the pixel defining film includes a plurality of circular protrusions on the top surface of the pixel defining film, and the first wiring is between the adjacent circular protrusions.

According to one or more embodiments of the present disclosure, mobile electronic device including: a display panel including a substrate and a display element layer on the substrate, wherein the display element layer includes: a pixel defining film delimiting a plurality of sub-pixels; a first electrode of each of the plurality of sub-pixels in an opening of the pixel defining film; a first wiring on the pixel defining film between the neighboring sub-pixels; a light-emitting stack on the first electrode and the pixel defining film including the first wiring, and disconnected around the first wiring; and a second electrode on the light-emitting stack, wherein a top surface of the pixel defining film around the first wiring is not flat and has a cross-sectional shape of a first pattern, and a top surface of the first wiring is not flat and has a cross-sectional shape of a second pattern.

In one or more embodiments, the first pattern of the pixel defining film includes a trench in which the first wiring is located.

In one or more embodiments, the second pattern of the first wiring has a cross-sectional structure of a positive tapered shape.

In one or more embodiments, the second pattern of the first wiring has a triangular shape having a width that gradually narrows from a bottom surface of the trench to a top thereof.

In one or more embodiments, the second pattern of the first wiring includes at least one groove at the top surface of the first wiring.

In the display device and the mobile electronic device including the same according to one or more embodiments, leakage current and color crosstalk may be reduced or prevented by disconnecting a light-emitting stack between neighboring sub-pixels.

The effects, aspects, and features of embodiments of the present disclosure are not limited to the above-described effects, aspects, and features, and other effects, aspects, and features, which are not described herein will become apparent to those skilled in the art from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIGS. 5 and 6 are layout diagrams illustrating embodiments of the display area of FIG. 4;

FIG. 7 is a cross-sectional view illustrating an example of a display panel taken along the line 11-11′ of FIG. 5;

FIG. 8 is a perspective view illustrating a head mounted display according to one or more embodiments;

FIG. 9 is an exploded perspective view illustrating an example of the head mounted display of FIG. 8;

FIG. 10 is a perspective view illustrating a head mounted display according to one or more embodiments;

FIG. 11 is a cross-sectional view schematically showing a display element layer of a display panel according to one or more embodiments;

FIG. 12 is a flowchart illustrating a manufacturing method of a display panel according to one or more embodiments;

FIGS. 13-16 are cross-sectional views illustrating a method of manufacturing a display element layer of a display panel according to one or more embodiments;

FIG. 17 is a cross-sectional view schematically illustrating a first wiring and a light-emitting stack of a display panel according to a comparative example;

FIGS. 18 and 19 are cross-sectional views schematically illustrating a pixel defining film and a first wiring according to one or more embodiments;

FIGS. 20 and 21 are conceptual diagrams illustrating a method of forming a first wiring according to one or more embodiments; and

FIGS. 22-30 are cross-sectional views schematically illustrating a pixel defining film and a first wiring according to one or more embodiments.

FIG. 31 is a block diagram of an electronic device according to one embodiment.

FIGS. 32, 33 and 34 are schematic diagrams of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Features of various embodiments of the present disclosure may be combined partially or totally. As will be clearly appreciated by those skilled in the art, technically various interactions and operations are possible. Various embodiments can be practiced individually or in combination.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific example embodiments will be described with reference to the accompanying drawings.

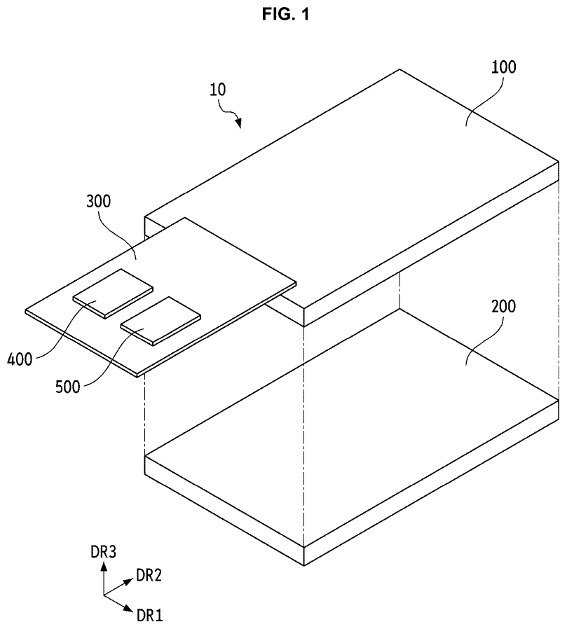

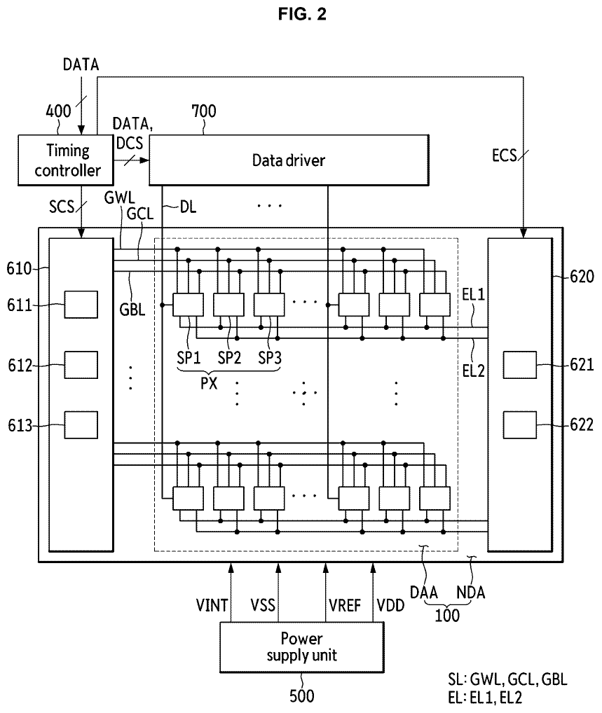

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and augmented reality, and/or the like.

The display device 10 according to one or more embodiments includes a display panel 100, a heat dissipation layer 200, a circuit board 300, a timing controller 400, and a power supply circuit (i.e., a power supply unit) 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 includes a display area DAA for displaying an image and a non-display area NDA that does not display an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

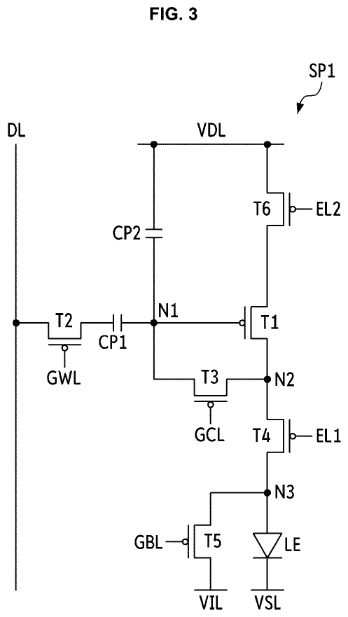

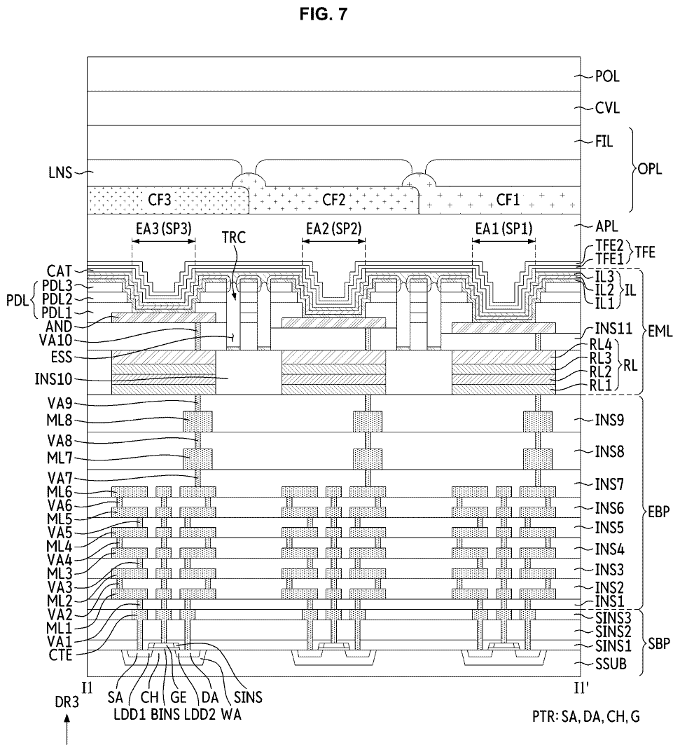

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to one write scan line GWL from among the plurality of write scan lines GWL, one control scan line GCL from among the plurality of control scan lines GCL, one bias scan line GBL from among the plurality of bias scan lines GBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA includes a scan driver 610, an emission driver 620, and the data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), and/or aluminum (AI) having high thermal conductivity.

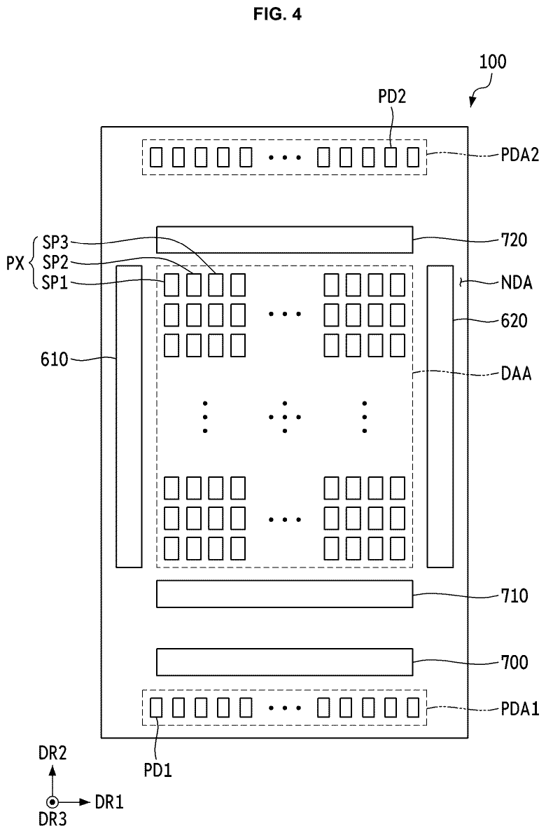

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing controller 400 may receive digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate a plurality of panel driving voltages according to a power voltage from the outside. For example, the power supply circuit 500 may generate a reference voltage VREF, a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing controller 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, similarly to the scan driver 610, the emission driver 620, and the data driver 700, each of the timing controller 400 and the power supply circuit 500 may be disposed in the non-display area NDA of the display panel 100. In this case, the timing controller 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing controller 400 and the power supply circuit 500 may be disposed between the data driver 700 and the first pad portion PDA1 (see FIG. 4).

FIG. 3 is an equivalent circuit diagram of a first sub-pixel according to one or more embodiments.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of a first transistor T1. The emission amount of the light-emitting element LE may be proportional to the driving current. The light-emitting element LE may be disposed between a fourth transistor T4 (or a third node N3) and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode (OLED) including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (e.g., the driving current) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and the third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 (or the first node N1) and the second driving voltage line VDL. The second capacitor CP2 includes one electrode connected to the gate electrode of the first transistor T1 (or the first node N1) and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

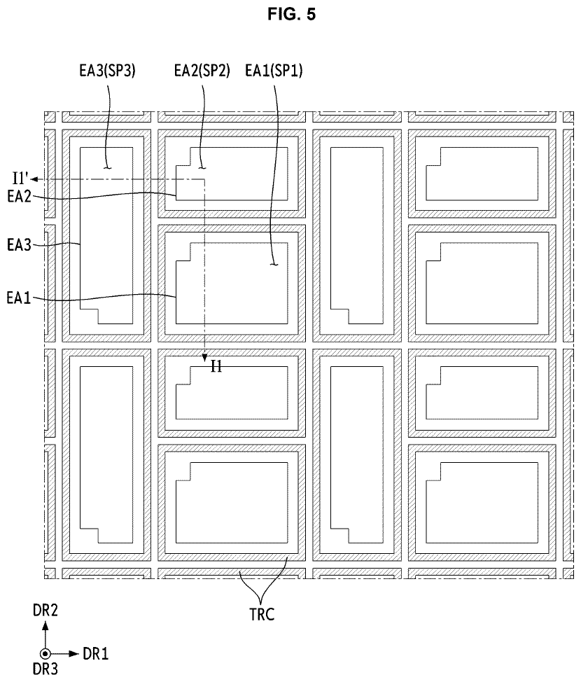

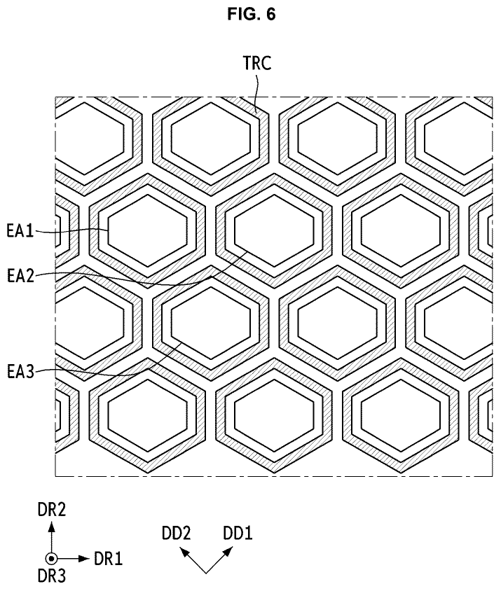

FIGS. 5 and 6 are layout diagrams illustrating embodiments of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIG. 6, but the present disclosure is not limited thereto. The first emission area EA1, the second emission area EA2, and the third emission area EA3 may have a polygonal shape other than a hexagon, a circular shape, an elliptical shape, and/or an atypical shape in a plan view.

As shown in FIG. 5, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In addition, the second emission area EA2 and the third emission area EA3 may be adjacent to each other in the first direction DR1. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is shown in FIGS. 5 and 6 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged as shown in FIG. 6. PENTILE® is a registered trademark of Samsung Display Co., Ltd., Republic of Korea.

FIG. 7 is a cross-sectional view illustrating an example of a display panel taken along the line 11-11′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB and the gate electrode GE of the pixel transistor PTR. The first semiconductor insulating film SINS1 may be formed of silicon carbonitride (SiCN) and/or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be disposed on the second semiconductor insulating film SINS2. Each of the plurality of contact terminals CTE may be connected to one of the gate electrode GE, the source region SA, or the drain region DA of each of the pixel transistors PTR through a hole penetrating the first semiconductor insulating film SINS1 and the second semiconductor insulating film INS2. The plurality of contact terminals CTE may be formed of copper (Cu), aluminum (AI), tungsten (W), molybdenum (Mo), chromium (Cr), gold (Au), titanium (Ti), nickel (Ni), and/or neodymium (Nd), or an alloy including one or more of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate and/or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light-emitting element backplane EBP includes a plurality of conductive layers ML1 to ML8, a plurality of vias VA1 to VA9, and a plurality of insulating films INS1 to INS9. In the light-emitting element backplane EBP, the plurality of insulating films INS1 to INS9 may be disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9 and may be connected to the exposed eighth conductive layer ML8. The ninth vias VA9 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, a first electrode AND, a light-emitting stack IL, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

Each of the fourth reflective electrodes RL4 may be disposed on the third reflective electrode RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å. However, in one or more embodiments, the thickness of the second reflective electrode RL2 may be substantially the same as the thickness of each of the first reflective electrode RL1, the third reflective electrode RL3, and the fourth reflective electrode RL4.

The tenth insulating film INS10 may be disposed on the ninth insulating film INS9. The tenth insulating film INS10 may be disposed between the reflective electrode layers RL adjacent to each other in a horizontal direction (e.g., the first direction or the second direction DR2). The tenth insulating film INS10 may be formed of a silicon oxide (SiOx)-based inorganic film, but the present disclosure is not limited thereto.

The eleventh insulating film INS11 may be disposed on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, from among light emitted from the light-emitting elements LE.

In order to match the resonance distance of the light emitted from the light-emitting elements LE in at least one of the first sub-pixel SP1, the second sub-pixel SP2, or the third sub-pixel SP3, the tenth insulating film INS10 or the eleventh insulating film INS11 may not be disposed under the first electrode AND. For example, in one or more embodiments, the first electrode AND of the first sub-pixel SP1 may be directly disposed on the reflective electrode layer RL. The eleventh insulating film INS11 may be disposed under the first electrode AND of the second sub-pixel SP2. In one or more embodiments, the tenth insulating film INS10 and the eleventh insulating film INS11 may be disposed under the first electrode AND of the third sub-pixel SP3. However, in one or more embodiments, in each of the first, second, and third sub-pixels SP1, SP2, and SP3, the eleventh insulating film INS11 may be disposed under the first electrode AND, and the thickness in the third direction DR3 of the eleventh insulating film INS11 may be different in each of the first sub-pixel SP1, the second sub-pixel SP2, and the third sub-pixel SP3.

In summary, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The present disclosure is not limited to the above examples.

In addition, although the tenth insulating film INS10 and the eleventh insulating film INS11 are illustrated in the present disclosure, a twelfth insulating film disposed under the first electrode AND of the first sub-pixel SP1 may be added. In this case, the eleventh insulating film INS11 and the twelfth insulating film may be disposed under the first electrode AND of the second sub-pixel SP2, and the tenth insulating film INS10, the eleventh insulating film INS11, and the twelfth insulating film may be disposed under the first electrode AND of the third sub-pixel SP3.

Each of the tenth vias VA10 may penetrate the tenth insulating film INS10 and/or the eleventh insulating film INS11 in the first sub-pixel SP1, the second sub-pixel SP2, and the third sub-pixel SP3 and may be connected to the exposed fourth reflective electrode RL4. The tenth vias VA10 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2.

The first electrode AND of each of the light-emitting elements LE may be disposed on the eleventh insulating film INS11 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light-emitting elements LE may be titanium nitride (TiN).

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. In one or more embodiments, the tenth insulating film INS10 may be partially recessed at each of the plurality of trenches TRC.

At least one trench TRC may be disposed between the neighboring sub-pixels SP1, SP2, and SP3. Although FIG. 7 illustrates that two trenches TRC are disposed between the neighboring sub-pixels SP1, SP2, and SP3, the present disclosure is not limited thereto.

The light-emitting stack IL may include a plurality of intermediate layers. FIG. 7 illustrates that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two intermediate layers.

In the three-tandem structure, the light-emitting stack IL may have a tandem structure including a plurality of stack layers IL1, IL2, and IL3 that emit different lights. For example, the light-emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity or an empty space may be disposed in the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the neighboring sub-pixels SP1, SP2, and SP3. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 7. For example, the light-emitting stack IL may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer for supplying electrons to one intermediate layer and supplying charges to the other intermediate layer may be disposed between the two intermediate layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. Further, the third stack layer IL3 may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen and/or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and/or silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) and/or aluminum oxide (AIOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, and/or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color from among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color from among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction (e.g., the third direction DR3).

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, and/or polyimide resin.

The cover layer CVL may be disposed on the filling layer FIL. The cover layer CVL may be a glass substrate and/or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and/or a phase retardation film. For example, the phase retardation film may be a λ/4 plate (e.g., quarter-wave plate), but the present disclosure is not limited thereto. However, when visibility degradation caused by reflection of external light is sufficiently overcome by the first to third color filters CF1, CF2, and CF3, the polarizing plate may be omitted.

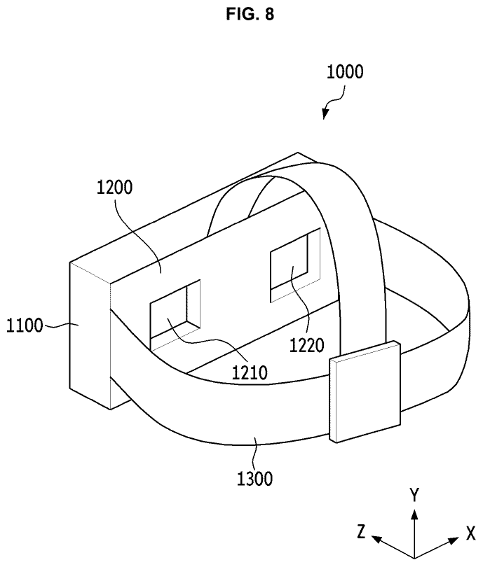

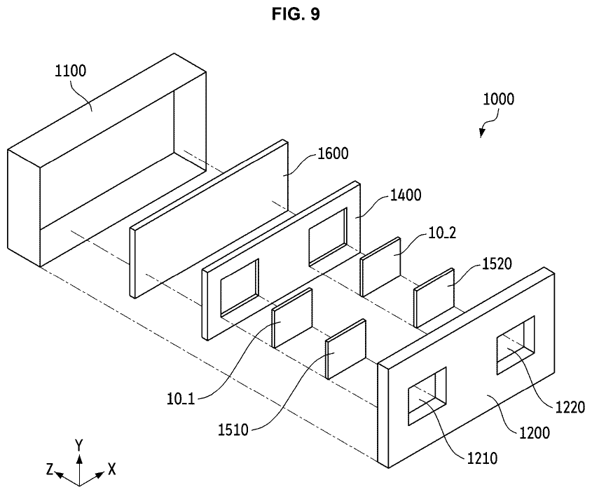

FIG. 8 is a perspective view illustrating a head mounted display according to one or more embodiments. FIG. 9 is an exploded perspective view illustrating an example of the head mounted display of FIG. 8.

Referring to FIGS. 8 and 9, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220.

Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 102, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

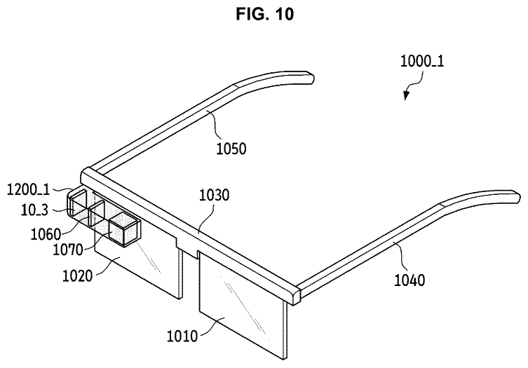

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 10 is a perspective view illustrating a head mounted display according to one or more embodiments.

Referring to FIG. 10, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 103, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

In the display panel 100 (see FIG. 4), unintended leakage current may be generated between the neighboring sub-pixels SP1, SP2, and SP3 (see FIG. 7) as the distance between the sub-pixels SP1, SP2, and SP3 decreases. The leakage current may be generated through some conductive layers of the light-emitting stack IL (see FIG. 7) disposed between the first electrode AND (see FIG. 7) and the second electrode CAT (see FIG. 7) of each of the sub-pixels SP1, SP2, and SP3. The leakage current is known to be the cause of color crosstalk between the neighboring sub-pixels SP1, SP2, and SP3.

In the embodiment of FIG. 7, by forming the plurality of trenches TRC (see FIG. 7) penetrating the pixel defining film PDL (see FIG. 7) between the neighboring sub-pixels SP1, SP2, and SP3, the light-emitting stack IL is disconnected at the plurality of trenches TRC during the deposition process of the light-emitting stack IL. The light-emitting stack IL is disconnected around the plurality of trenches TRC according to the step coverage characteristics due to the plurality of trenches TRC.

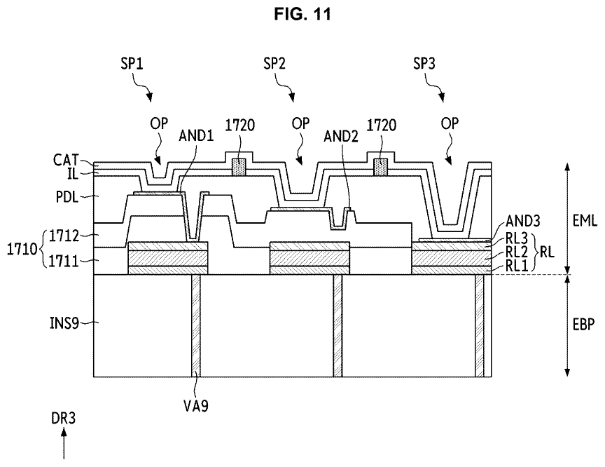

In various embodiments of the present disclosure below with reference to FIGS. 11-30, unlike in the embodiment of FIG. 7, a first wiring 1720 (see FIG. 11) is formed between the neighboring sub-pixels SP1, SP2, and SP3, and a suitable volage (e.g., a preset voltage) is applied to the first wiring 1720 after the light-emitting stack IL is deposited entirely, thereby disconnecting the light-emitting stack IL. When the voltage is applied to the first wiring 1720, the first wiring 1720 is heated, and the heated first wiring 1720 disconnects the light-emitting stack IL deposited around it. In this way, disconnecting the light-emitting stack IL by using the first wiring 1720 that emits heat may be referred to as a “Joule heating method.”

In the present disclosure, the first wiring 1720 may be replaced by terms such as “heating wiring,” “dummy wiring,” and/or “Joule heating wiring,” but the present disclosure is not limited to the terms of the first wiring 1720.

Hereinafter, the display device 10 (see FIG. 1) according to one or more embodiments in which the light-emitting stack IL is disconnected between the neighboring sub-pixels SP1, SP2, and SP3 by using the Joule heating method, and a manufacturing method thereof will be described.

FIG. 11 is a cross-sectional view schematically showing a display element layer of a display panel according to one or more embodiments. For example, at least a part of the display element layer EML illustrated in FIG. 11 may be similar to that of the display panel 100 illustrated in FIG. 7. Other layers except the display element layer EML shown in FIG. 11, for example, the structure above the display element layer EML and the structure below the display element layer EML may be substantially the same as those of the display panel 100 shown in FIG. 7. Therefore, the description of the other layers except the display element layer EML shown in FIG. 11, for example, the structure above the display element layer EML and the structure below the display element layer EML will be replaced by the description with reference to FIG. 7.

Referring to FIG. 11, unlike in the embodiment of FIG. 7, the display element layer EML according to one or more embodiments includes the first wiring 1720 that emits heat when the suitable volage (e.g., the preset voltage) is applied thereto, but does not include the trench TRC (see FIG. 7).

The display element layer EML includes the reflective electrode layer RL disposed on the ninth insulating film INS9 of the light-emitting element backplane EBP; a differential film 1710 covering the reflective electrode layer RL; first electrodes AND1, AND2, AND3, and the pixel defining film PDL disposed on the differential film 1710; the first wiring 1720 disposed on the pixel defining film PDL between the neighboring sub-pixels SP1, SP2, and SP3; the light-emitting stack IL deposited on the pixel defining film PDL including the first wiring 1720 and disconnected around the first wiring 1720; and the second electrode CAT deposited on the light-emitting stack IL and the first wiring 1720.

The reflective electrode layer RL may include, for example, a first reflective electrode RL1, a second reflective electrode RL2, and a third reflective electrode RL3 that are stacked in sequence.

The first reflective electrode RL1 may be formed of copper (Cu), aluminum (AI), tungsten (W), molybdenum (Mo), chromium (Cr), gold (Au), titanium (Ti), nickel (Ni), and/or neodymium (Nd), and/or an alloy containing one or more of them.

The second reflective electrode RL2 may be disposed on the first reflective electrode RL1. The second reflective electrodes RL2 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them.

The third reflective electrode RL3 may be disposed on the second reflective electrode RL2. The third reflective electrode RL3 may include a metal having a high reflectance to facilitate reflection of light. The third reflective electrode RL3 may be formed of aluminum (AI), a stacked structure (Ti/Al/Ti) of aluminum and titanium, a stacked structure (ITO/AI/ITO) of aluminum and ITO, an APC alloy, which is an alloy of silver (Ag), palladium (Pd), and copper (Cu), and/or a stacked structure (ITO/APC/ITO) of the APC alloy and ITO, but the present disclosure is not limited thereto.

The differential film 1710 may be disposed on and around the reflective electrode RL. The differential film 1710 may include a first differential film 1711, and a second differential film 1712 disposed on the first differential film 1711. The differential film 1710 may be commonly stacked in the first sub-pixel SP1 and the second sub-pixel SP2, but may not be stacked in the third sub-pixel SP3. The differential film 1710 serves to vary a distance between the first electrode AND and the reflective electrode RL for each of the first sub-pixel SP1, the second sub-pixel SP2, and the third sub-pixel SP3.

In the first sub-pixel SP1, the first differential film 1711, the second differential film 1712, and the first electrode AND1 of the first sub-pixel SP1 may be sequentially stacked on the reflective electrode RL.

In the second sub-pixel SP2, the second differential film 1712 and the first electrode AND2 of the second sub-pixel SP2 may be sequentially stacked on the reflective electrode RL.

In the third sub-pixel SP3, the first electrode AND3 of the third sub-pixel SP3 may be disposed on the reflective electrode RL.

The distance between the first electrode AND and the reflective electrode RL may be different for each of the first sub-pixel SP1, the second sub-pixel SP2, and the third sub-pixel SP3. For example, the distance between the first electrode AND and the reflective electrode RL may be the longest in the first sub-pixel SP1 and shortest in the third sub-pixel SP3 due to the difference in thickness of the differential film 1710.

According to one or more embodiments, the pixel defining film PDL that delimits the sub-pixels SP1, SP2, and SP3 is disposed on the first electrodes AND1, AND2, and AND3 and the differential film 1710. The pixel defining film PDL is disposed to cover both ends of the first electrodes AND1, AND2, and AND3 of the respective sub-pixels SP1, SP2, and SP3. In an opening OP of the pixel defining film PDL, each of the first electrodes AND1, AND2, and AND3 is disposed to be partially exposed during processing.

The first wiring 1720 is disposed on the pixel defining film PDL between the neighboring sub-pixels SP1, SP2, and SP3. The first wiring 1720 may be disposed to be around (e.g., to surround) the first electrodes AND1, AND2, and AND3 of the respective sub-pixels SP1, SP2, and SP3. The first wiring 1720 may receive a suitable volage (e.g., a preset voltage) through a pad disposed in the non-display area NDA of FIG. 4.

The light-emitting stack IL is deposited on the first electrodes AND1, AND2, and AND3, the first wiring 1720, and the pixel defining film PDL. At least a part of the light-emitting stack IL is disconnected as the suitable volage (e.g., the preset voltage) is applied to the first wiring 1720 after the light-emitting stack IL is entirely deposited.

The light-emitting stack IL may include at least one conductive layer that is disconnected on and around the first wiring 1720. Here, the conductive layer of the light-emitting stack IL that is disconnected includes at least one of a hole injection layer (e.g., HIL), a hole transporting layer (e.g., HTL), an electron transporting layer (e.g., ETL), a charge generating layer (e.g., CGL), or a P-doped layer (e.g., PHIL).

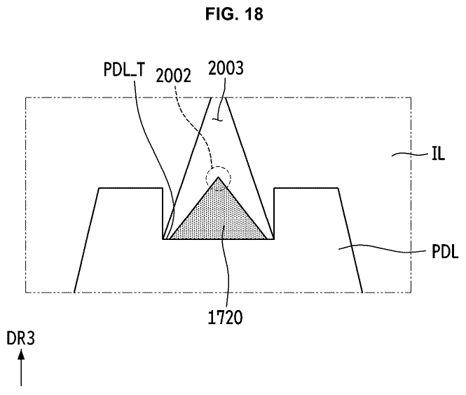

In one or more embodiments of the present disclosure, in order to facilitate the disconnection of the light-emitting stack IL when a voltage is applied to the first wiring 1720 to disconnect the light-emitting stack IL, the pixel defining film PDL is designed to have a cross-sectional shape of a suitable first pattern (e.g., a predetermined first pattern) around the first wiring 1720, and the first wiring 1720 is designed to have a cross-sectional shape of a suitable second pattern (e.g., a predetermined second pattern). The first pattern of the pixel defining film PDL and the second pattern of the first wiring 1720 will be described later in detail with reference to FIGS. 18-30.

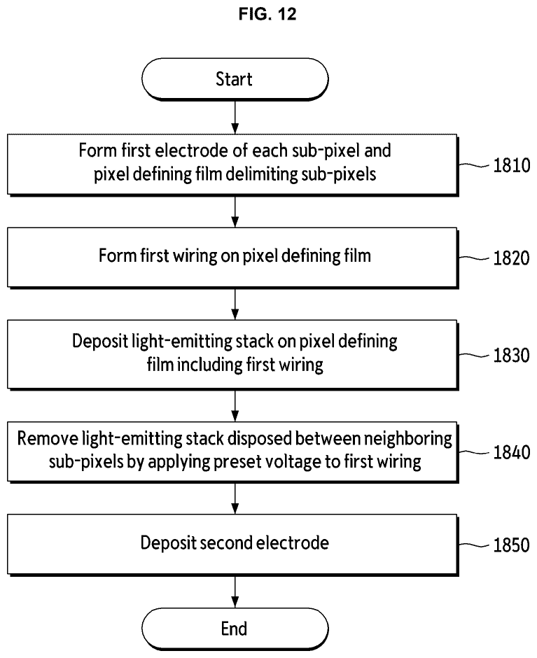

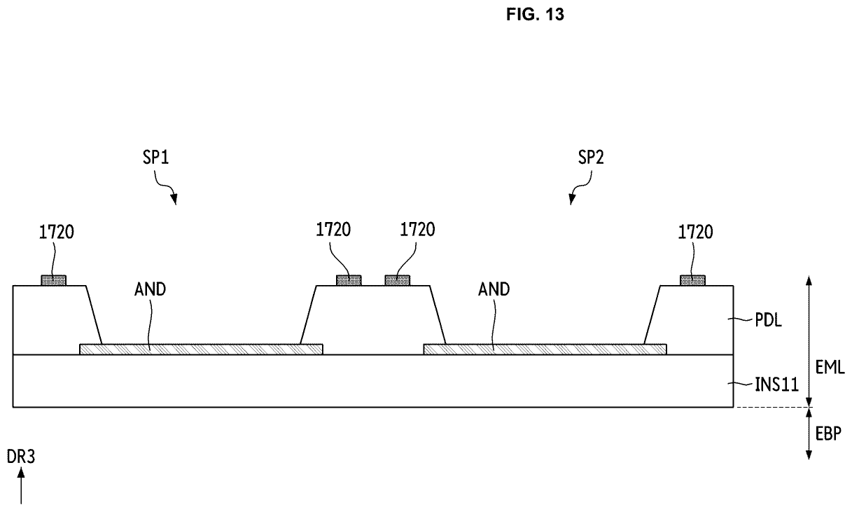

FIG. 12 is a flowchart illustrating a manufacturing method of a display panel according to one or more embodiments. FIGS. 13-16 are cross-sectional views illustrating a method of manufacturing a display element layer of a display panel according to one or more embodiments.

Hereinafter, a method of manufacturing the display element layer EML of the display panel 100 according to one or more embodiments will be described in connection with FIGS. 12-16.

Referring to FIG. 12, in operation 1810, the first electrodes AND (see FIG. 7) of the sub-pixels SP1, SP2, and SP3 (see FIG. 7) and the pixel defining film PDL that delimits the sub-pixels SP1, SP2, and SP3 are formed. For example, the pixel defining film PDL (see FIG. 11) that delimits the sub-pixels SP1, SP2, and SP3 (see FIG. 11) is disposed on the first electrodes AND1, AND2, and AND3 (see FIG. 11) and the differential film 1710 (see FIG. 11). The pixel defining film PDL is disposed to cover both ends of the first electrodes AND1, AND2, and AND3 of the sub-pixels SP1, SP2, and SP3, and parts of the first electrodes AND1, AND2, and AND3 are disposed in the openings OP (see FIG. 11) of the pixel defining film PDL so as to be exposed to the process.

Referring to FIGS. 12 and 13, in operation 1820, the first wiring 1720 is formed on the pixel defining film PDL. The first wiring 1720 has a cross-sectional shape of a suitable second pattern (e.g., a predetermined second pattern).

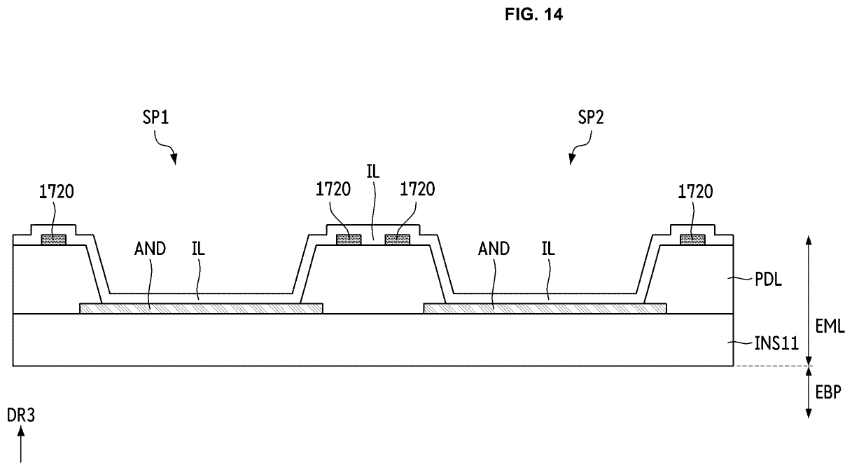

Referring to FIGS. 12 and 14, in operation 1830, the light-emitting stack IL is deposited on the pixel defining film PDL including the first wiring 1720. For example, the light-emitting stack IL is deposited on the entire surface of the semiconductor substrate SSUB (see FIG. 7). Thus, the light-emitting stack IL is deposited on the first electrodes AND1, AND2, and AND3, the first wiring 1720, and the pixel defining film PDL.

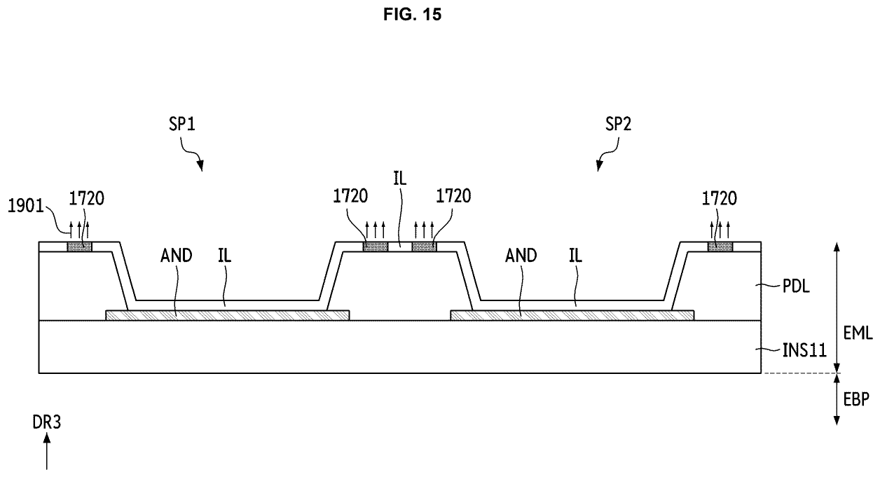

Referring to FIGS. 12 and 15, in operation 1840, the light-emitting stack IL disposed between the neighboring sub-pixels SP1, SP2, and SP3 is removed by applying a suitable volage (e.g., a preset voltage) to the first wiring 1720. The suitable volage (e.g., the preset voltage) may be, for example, about 10V to about 3000V, but the present disclosure is not limited thereto. The temperature of the first wiring 1720 applied with the suitable volage (e.g., the preset voltage) may increase up to about 550° C. The first wiring 1720 whose temperature has risen as described above may disconnect the light-emitting stack IL deposited around it, as indicated by a reference numeral 1901 in FIG. 15.

According to one or more embodiments of the present disclosure, in order to facilitate the disconnection of the light-emitting stack IL when the voltage is applied to the first wiring 1720 to disconnect the light-emitting stack IL, the pixel defining film PDL is designed to have a cross-sectional shape of a suitable first pattern (e.g., a predetermined first pattern) around the first wiring 1720, and the first wiring 1720 is designed to have a cross-sectional shape of a suitable second pattern (e.g., a predetermined second pattern). The first pattern of the pixel defining film PDL and the second pattern of the first wiring 1720 will be described later in detail with reference to FIGS. 18-30.

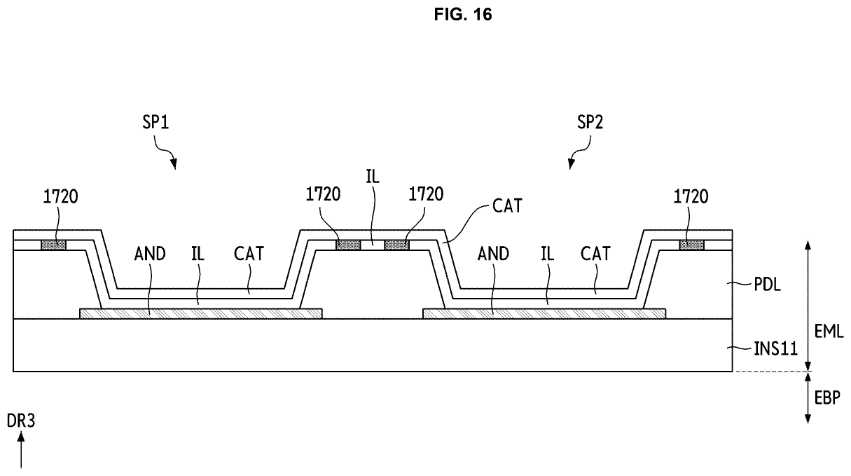

Referring to FIGS. 12 and 16, in operation 1850, the second electrode CAT is deposited. The second electrode CAT is commonly disposed in the plurality of sub-pixels SP1, SP2, and SP3. The second electrode CAT may be a common layer in which the plurality of sub-pixels SP1, SP2, and SP3 are connected to each other in the area between them. The second electrode CAT is continuously extended while covering the light-emitting stack IL in the opening OP of the pixel defining film PDL and covering the first wiring 1720 and the light-emitting stack IL between the neighboring sub-pixels SP1, SP2, and SP3.

As described above with reference to FIG. 7, the encapsulation layer TFE, the organic film APL, the optical layer OPL, the cover layer CVL, and the polarizing plate POL may be stacked on the second electrode CAT.

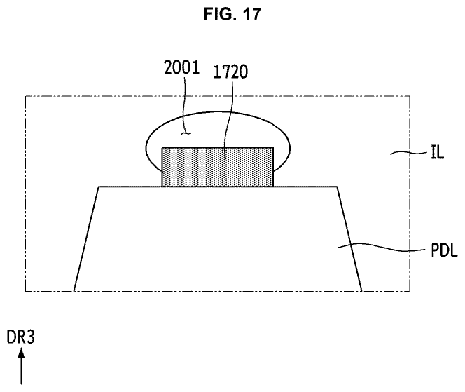

FIG. 17 is a cross-sectional view schematically illustrating a first wiring and a light-emitting stack of a display panel according to a comparative example.

Referring to FIG. 17, the first wiring 1720 according to the comparative example has a rectangular cross-sectional structure and includes a flat top surface. In a Joule heating method according to the comparative example, heat generated from the first wiring 1720 may not be concentrated in an upward direction of the first wiring 1720, and, accordingly, a defect in which the light-emitting stack IL is not disconnected may occur as indicated by a reference numeral 2001 in FIG. 17. If the light-emitting stack IL is not disconnected, leakage current and color crosstalk may occur, which needs to be resolved.

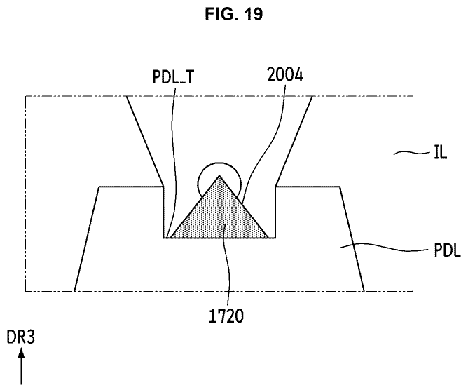

FIGS. 18 and 19 are cross-sectional views schematically illustrating a pixel defining film and a first wiring according to one or more embodiments.

Referring to FIGS. 18 and 19, the display panel 100 includes the first wiring 1720 disposed on the pixel defining film PDL between the neighboring sub-pixels SP1, SP2, and SP3.

The top surface of the pixel defining film PDL around the first wiring 1720 is not flat and has a cross-sectional shape of a suitable first pattern (e.g., a predetermined first pattern). In addition, the top surface of the first wiring 1720 is not flat, either, and has a cross-sectional shape of a suitable second pattern (e.g., a predetermined second pattern).

The first pattern of the pixel defining film PDL includes a trench PDL_T in which the first wiring 1720 is deposited. The trench PDL_T of the pixel defining film PDL allows the light-emitting stack IL to be disconnected due to the step coverage characteristics when the light-emitting stack IL is deposited on the pixel defining film PDL.

The second pattern of the first wiring 1720 has a cross-sectional structure of a positive tapered shape. For example, the first wiring 1720 has a cross-sectional structure with a decreasing width as it goes from the bottom surface of the trench PDL_T toward the top thereof.

The second pattern of the first wiring 1720 includes a triangular shape whose width becomes narrower as it goes from the bottom surface of the trench PDL_T toward the top thereof. Accordingly, the first wiring 1720 has a pointed protruding portion 2002. When the suitable volage (e.g., the preset voltage) is applied to the first wiring 1720 to disconnect the light-emitting stack IL, the temperature of the protruding portion 2002 of the first wiring 1720 may be higher than that of other portions thereof. Accordingly, a portion 2003 of the light-emitting stack IL deposited on the first wiring 1720 may be more easily disconnected as compared to the embodiment of FIG. 17.

In addition, as shown in FIG. 19, the first wiring 1720 includes a tapered side surface, that is, an inclined surface 2004. The inclined surface 2004 of the first wiring 1720 may increase a contact area between the first wiring 1720 and the deposition surface of the light-emitting stack IL. Accordingly, the portion 2003 of the light-emitting stack IL deposited on and around the first wiring 1720 may be more easily disconnected as compared to the embodiment of FIG. 17.

As stated above, in the display panel 100 of the present disclosure, the pixel defining film PDL includes the cross-sectional structure of the first pattern, and the first wiring 1720 includes the cross-sectional structure of the second pattern. With this configuration, the suitable volage (e.g., the preset voltage) for driving the first wiring 1720 can be reduced. In addition, even if the suitable volage (e.g., the preset voltage) for driving the first wiring 1720 is fixed, the light-emitting stack IL can be disconnected more easily and stably as compared to the Joule heating method according to the comparative example shown in FIG. 17.

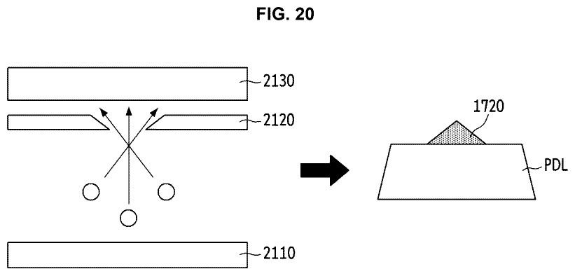

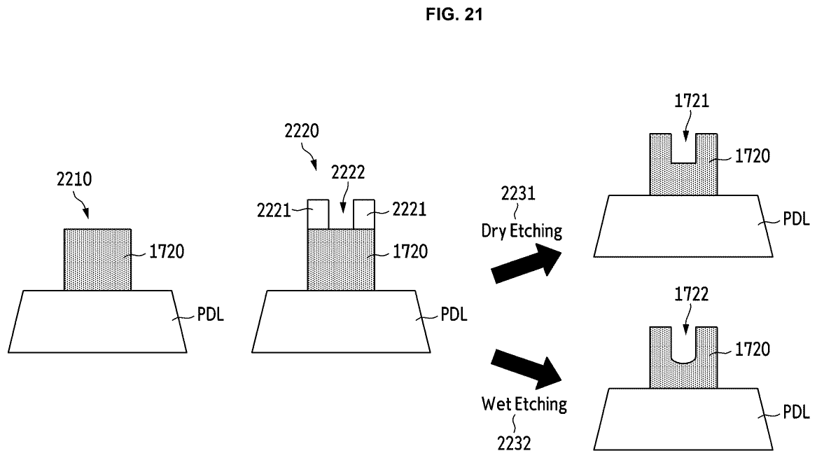

FIGS. 20 and 21 are conceptual diagrams illustrating a method of forming a first wiring according to one or more embodiments.

Referring to FIG. 20, a method of forming the first wiring 1720 may include a sputtering process. For example, a deposition substrate 2130 (e.g., the display panel 100 in FIG. 4) is aligned to face a deposition source 2110. A deposition mask 2120 is disposed between the deposition substrate 2130 (e.g., the display panel 100 in FIG. 4) and the deposition source 2110. The deposition mask 2120 may include an opening through which a deposition material emitted from the deposition source 2110 passes, and the opening may have a tip structure. Accordingly, the first wiring 1720 has a cross-sectional structure of a positive tapered shape including a tapered side surface, that is, the inclined surface 2004 (FIG. 19).

Referring to FIG. 21, grooves 1721 and 1722 may be formed on the top surface of the first wiring 1720 by a dry etching process and/or a wet etching process after the first wiring 1720 is deposited on the pixel defining film PDL. For example, as indicated by a reference numeral 2210, the first wiring 1720 may be deposited by performing a sputtering process on the pixel defining film PDL. Subsequently, as indicated by a reference numeral 2220, a photoresist pattern 2221 including an opening 2222 may be formed on the first wiring 1720. The opening 2222 of the photoresist pattern 2221 may be formed to cross the middle of the top surface of the first wiring 1720.

Subsequently, a dry etching process 2231 may be performed by using the photoresist pattern 2221 as a mask to form the groove 1721 on the top surface of the first wiring 1720 and remove the photoresist pattern 2221. Accordingly, the second pattern of the first wiring 1720 includes at least one groove 1721 formed on the top surface of the first wiring 1720. At this time, the bottom surface of the at least one groove 1721 formed on the top surface of the first wiring 1720 is flat.

Alternatively, a wet etching process 2232 may be performed by using the photoresist pattern 2221 as a mask to form a groove 1722 on the top surface of the first wiring 1720 and remove the photoresist pattern 2221. Accordingly, the second pattern of the first wiring 1720 includes at least one groove 1722 formed on the top surface of the first wiring 1720. The bottom surface of the at least one groove 1722 formed on the top surface of the first wiring 1720 is concave.

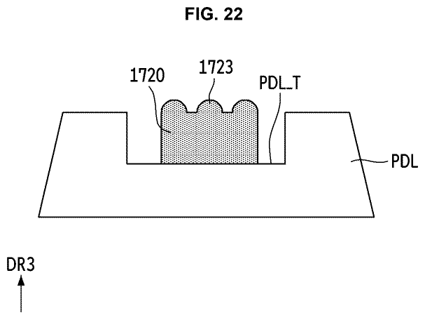

FIGS. 22-30 are cross-sectional views schematically illustrating a pixel defining film and a first wiring according to various embodiments.

In the embodiment shown in FIG. 22, the second pattern of the first wiring 1720 includes a plurality of circular protrusions 1723 formed on the top surface of the first wiring 1720, unlike in the embodiment shown in FIG. 18.

Referring to FIG. 22, the plurality of circular protrusions 1723 are formed on the top surface of the first wiring 1720. The circular protrusions 1723 of the first wiring 1720 increase the surface area between the first wiring 1720 and the deposition surface of the light-emitting stack IL deposited on the first wiring 1720. In the embodiment of FIG. 22 described above, due to the increase of the surface area between the first wiring 1720 and the deposition surface of the light-emitting stack IL deposited on the first wiring 1720, disconnection of the light-emitting stack IL on and around the first wiring 1720 is facilitated.

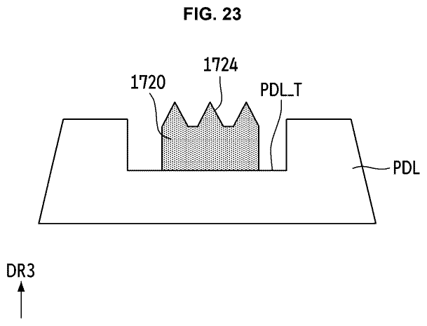

In the embodiment shown in FIG. 23, the second pattern of the first wiring 1720 includes a plurality of triangular protrusions 1724 formed on the top surface of the first wiring 1720, unlike in the embodiment shown in FIG. 18.

Referring to FIG. 23, the plurality of triangular protrusions 1724 are formed on the top surface of the first wiring 1720. The triangular protrusion 1724 may be referred to as a “spike (stud).” The triangular protrusions 1724 of the first wiring 1720 increase the surface area between the first wiring 1720 and the deposition surface of the light-emitting stack IL deposited on the first wiring 1720. In the embodiment of FIG. 23 described above, due to the increase of the surface area between the first wiring 1720 and the deposition surface of the light-emitting stack IL deposited on the first wiring 1720, disconnection of the light-emitting stack IL on and around the first wiring 1720 is facilitated.

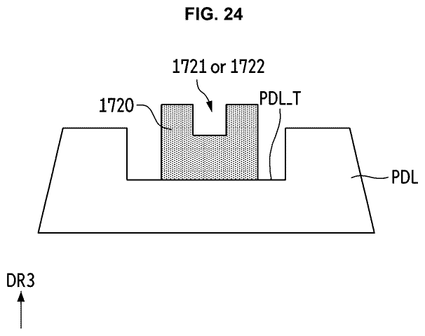

In the embodiment shown in FIG. 24, the second pattern of the first wiring 1720 includes at least one groove 1721 or 1722 formed on the top surface of the first wiring 1720, unlike in the embodiment shown in FIG. 18. The bottom surface of the at least one groove 1721 or 1722 formed on the top surface of the first wiring 1720 may be concave or flat.

Referring to FIG. 24, the at least one groove 1721 or 1722 is formed on the top surface of the first wiring 1720. The groove 1721 or 1722 of the first wiring 1720 may be formed by the dry etching process 2231 or the wet etching process 2232, as described with reference to FIG. 21. In the embodiment of FIG. 24, due to an increase of the surface area between the first wiring 1720 and the deposition surface of the light-emitting stack IL deposited on the first wiring 1720, disconnection of the light-emitting stack IL on and around the first wiring 1720 is facilitated.

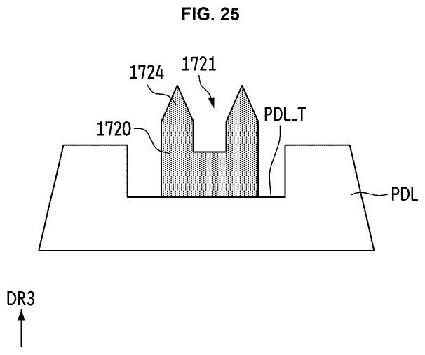

In the embodiment of FIG. 25, the second pattern of the first wiring 1720 includes the plurality of triangular protrusions 1724 formed on the top surface of the first wiring 1720, and the groove 1721 is formed between the adjacent triangular protrusions 1724, unlike in the embodiment shown in FIG. 18.

Referring to FIG. 25, the triangular protrusion 1724 may be referred to as a “spike (stud).” The triangular protrusions 1724 of the first wiring 1720 increase the surface area between the first wiring 1720 and the deposition surface of the light-emitting stack IL deposited on the first wiring 1720. The groove 1721 formed between the adjacent triangular protrusions 1724 may be formed by the dry etching process 2231 or the wet etching process 2232, as described with reference to FIG. 21. In the embodiment of FIG. 25, due to the increase of the surface area between the first wiring 1720 and the deposition surface of the light-emitting stack IL deposited on the first wiring 1720, disconnection of the light-emitting stack IL on and around the first wiring 1720 is facilitated.

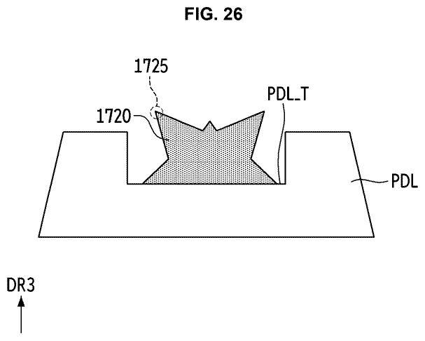

In the embodiment shown in FIG. 26, the second pattern of the first wiring 1720 includes a plurality of triangular protrusions 1725 formed on the top and side surfaces of the first wiring 1720, unlike in the embodiment shown in FIG. 18.

Referring to FIG. 26, the triangular protrusion 1725 may be referred to as a “spike (stud).” The plurality of triangular protrusions 1725 formed on the top and side surfaces of the first wiring 1720 increase the surface area between the first wiring 1720 and the deposition surface of the light-emitting stack IL deposited on the first wiring 1720. In the embodiment of FIG. 26, due to the increase of the surface area between the first wiring 1720 and the deposition surface of the light-emitting stack IL deposited on the first wiring 1720, disconnection of the light-emitting stack IL on and around the first wiring 1720 is facilitated.

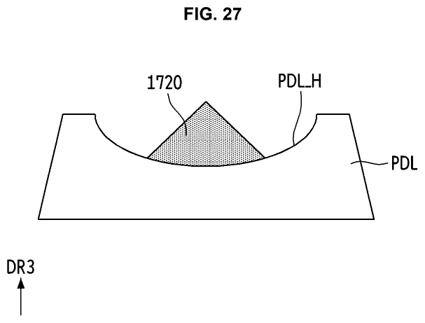

In the embodiment shown in FIG. 27, the trench formed in the pixel defining film PDL includes a concave bottom surface PDL_H, unlike in the embodiment shown in FIG. 18. In this embodiment of FIG. 27, the light-emitting stack IL may be disconnected due to the step coverage characteristics during the deposition process of the light-emitting stack IL. In the embodiment of FIG. 27, the thickness of the light-emitting stack IL around the first wiring 1720 is relatively small according to the step coverage characteristics of the pixel defining film PDL. Therefore, disconnection of the light-emitting stack IL around the first wiring 1720 is facilitated.

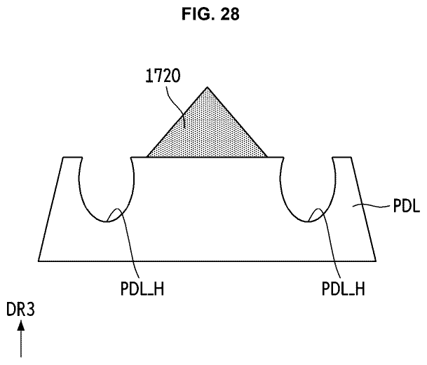

In the embodiment shown in FIG. 28, the first pattern of the pixel defining film PDL includes the trench having a height lower than that of the first wiring 1720, around (e.g., surrounding) the first wiring 1720, and having the concave bottom surface PDL_H, unlike in the embodiment shown in FIG. 18. In this embodiment of FIG. 28, the light-emitting stack IL may be disconnected due to the step coverage characteristics during the deposition process of the light-emitting stack IL. In the embodiment of FIG. 28, the thickness of the light-emitting stack IL around the first wiring 1720 is relatively small according to the step coverage characteristics of the pixel defining film PDL. Therefore, disconnection of the light-emitting stack IL around the first wiring 1720 is facilitated.

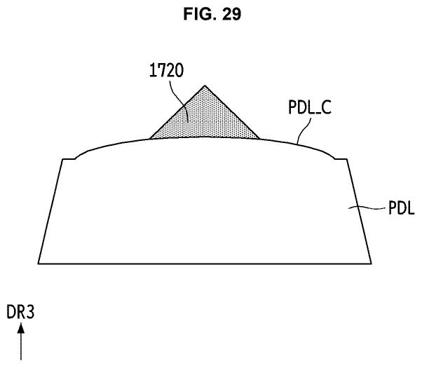

In the embodiment shown in FIG. 29, the first pattern of the pixel defining film PDL includes a convex top surface of the pixel defining film PDL, unlike in the embodiment shown in FIG. 18. The pixel defining film PDL has a convex top surface PDL_C between the neighboring sub-pixels SP1, SP2, and SP3.

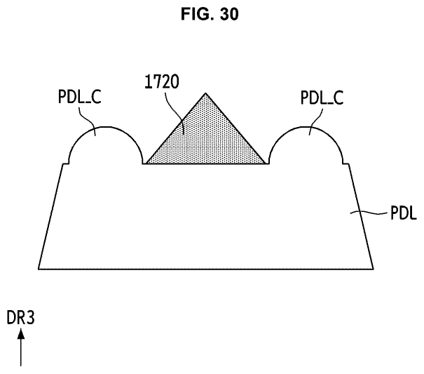

In the embodiment shown in FIG. 30, the first pattern of the pixel defining film PDL includes a plurality of circular protrusions PDL_C formed on the top surface of the pixel defining film PDL, and the first wiring 1720 is disposed between the adjacent circular protrusions PDL_C, unlike in the embodiment shown in FIG. 18. In this embodiment of FIG. 30, the light-emitting stack IL may be disconnected due to the step coverage characteristics of the pixel defining film PDL during the deposition process of the light-emitting stack IL. In the embodiment of FIG. 30, the thickness of the light-emitting stack IL around the first wiring 1720 is relatively small according to the step coverage characteristics of the pixel defining film PDL. Therefore, disconnection of the light-emitting stack IL around the first wiring 1720 is facilitated.

The display device according to the embodiment can be applied to various electronic devices. The electronic device according to one embodiment includes the display device described above and may further include modules or devices having additional functions in addition to the display device.

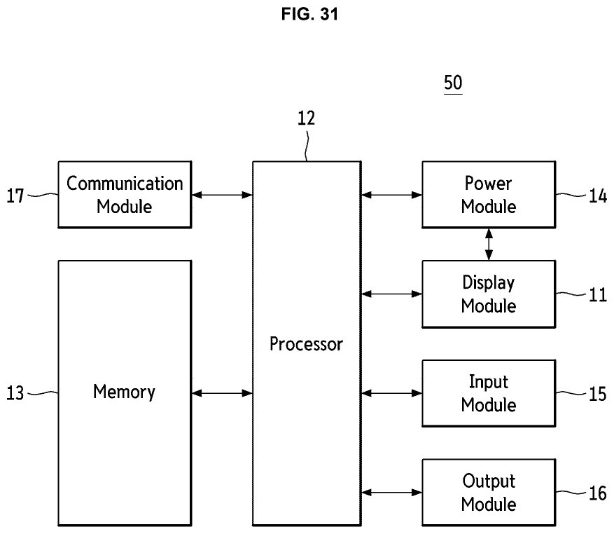

FIG. 31 is a block diagram of an electronic device according to one embodiment. Referring to FIG. 31, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

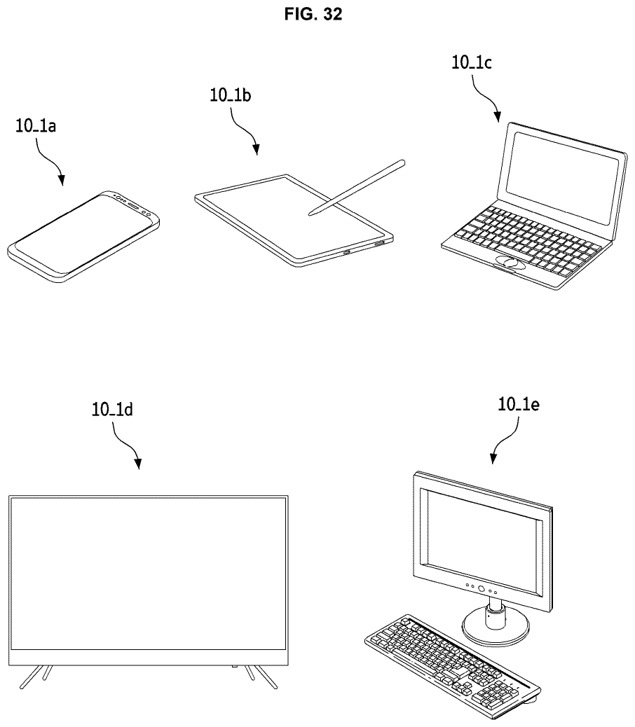

FIGS. 32, 33, and 34 are schematic diagrams of electronic devices according to various embodiments. FIGS. 32 to 34 illustrate examples of various electronic devices to which the display device according to the embodiments is applied.

FIG. 32 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 101e, they also include display modules and input modules similar to smartphones 10_1, and may additionally include communication modules in some cases.

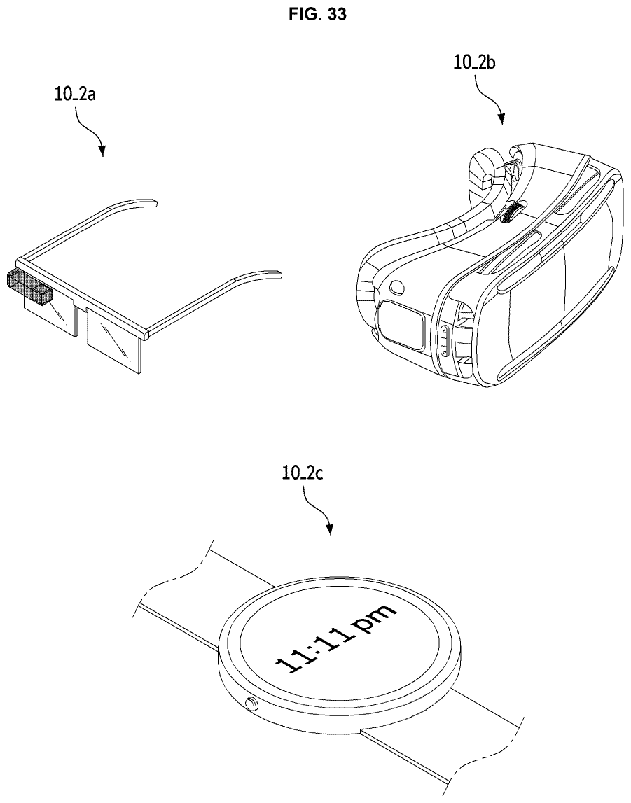

FIG. 33 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

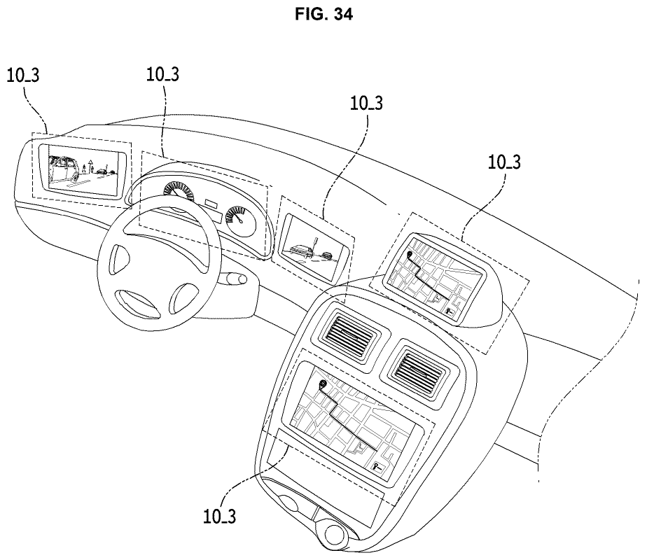

The smart watch 10_2c includes a biometric sensor as an input device, and may provide biometric information recognized by the biometric sensor to the user through the display module. FIG. 34 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims and their equivalents rather than the detailed description described above and all modifications and alterations derived from the claims and their equivalents fall within the scope of the present disclosure.

What is claimed is:

1. A display device comprising:
a substrate; and
a display element layer on the substrate,
wherein the display element layer comprises:
a pixel defining film delimiting a plurality of sub-pixels;
a first electrode of each of the plurality of sub-pixels located in an opening of the pixel defining film;
a first wiring on the pixel defining film between the neighboring sub-pixels;
a light-emitting stack on the first electrode and the pixel defining film comprising the first wiring, and disconnected around the first wiring; and
a second electrode on the light-emitting stack,
wherein a top surface of the pixel defining film around the first wiring is not flat and has a cross-sectional shape of a first pattern, and
wherein a top surface of the first wiring is not flat and has a cross-sectional shape of a second pattern.

2. The display device of claim 1, wherein the first pattern of the pixel defining film comprises a trench in which the first wiring is located.

3. The display device of claim 2, wherein the second pattern of the first wiring has a cross-sectional structure of a positive tapered shape.

4. The display device of claim 3, wherein the second pattern of the first wiring has a triangular shape having a width that gradually narrows from a bottom surface of the trench to a top surface of the trench.

5. The display device of claim 2, wherein the second pattern of the first wiring comprises at least one groove at the top surface of the first wiring.

6. The display device of claim 5, wherein a bottom surface of the at least one groove at the top surface of the first wiring is flat.

7. The display device of claim 5, wherein a bottom surface of the at least one groove at the top surface of the first wiring is concave.

8. The display device of claim 2, wherein the second pattern of the first wiring comprises a plurality of circular protrusions on the top surface of the first wiring.

9. The display device of claim 2, wherein the second pattern of the first wiring comprises a plurality of triangular protrusions on the top surface of the first wiring.

10. The display device of claim 9, wherein the second pattern of the first wiring further comprises a groove between the adjacent triangular protrusions.

11. The display device of claim 2, wherein the second pattern of the first wiring comprises a plurality of triangular protrusions on a side surface and the top surface of the first wiring.

12. The display device of claim 2, wherein the trench in the pixel defining film has a concave bottom surface.

13. The display device of claim 1, wherein the first pattern of the pixel defining film comprises a trench having a height lower than that of the first wiring, surrounding the first wiring, and having a concave bottom surface.

14. The display device of claim 1, wherein the first pattern of the pixel defining film comprises a convex top surface of the pixel defining film.

15. The display device of claim 1, wherein the first pattern of the pixel defining film comprises a plurality of circular protrusions on the top surface of the pixel defining film, and
wherein the first wiring is between the adjacent circular protrusions.

16. A mobile electronic device comprising:
a display panel comprising a substrate and a display element layer on the substrate,
wherein the display element layer comprises:
a pixel defining film delimiting a plurality of sub-pixels;
a first electrode of each of the plurality of sub-pixels in an opening of the pixel defining film;
a first wiring on the pixel defining film between the neighboring sub-pixels;
a light-emitting stack on the first electrode and the pixel defining film comprising the first wiring, and disconnected around the first wiring; and
a second electrode on the light-emitting stack,
wherein a top surface of the pixel defining film around the first wiring is not flat and has a cross-sectional shape of a first pattern, and
a top surface of the first wiring is not flat and has a cross-sectional shape of a second pattern.

17. The mobile electronic device of claim 16, wherein the first pattern of the pixel defining film comprises a trench in which the first wiring is located.

18. The mobile electronic device of claim 17, wherein the second pattern of the first wiring has a cross-sectional structure of a positive tapered shape.

19. The mobile electronic device of claim 18, wherein the second pattern of the first wiring has a triangular shape having a width that gradually narrows from a bottom surface of the trench to a top surface of the trench.

20. An electronic device comprising:
A display device including a screen,
wherein the display device comprises
a substrate; and
a display element layer on the substrate,
wherein the display element layer comprises:
a pixel defining film delimiting a plurality of sub-pixels;
a first electrode of each of the plurality of sub-pixels located in an opening of the pixel defining film;
a first wiring on the pixel defining film between the neighboring sub-pixels;
a light-emitting stack on the first electrode and the pixel defining film comprising the first wiring, and disconnected around the first wiring; and
a second electrode on the light-emitting stack,
wherein a top surface of the pixel defining film around the first wiring is not flat and has a cross-sectional shape of a first pattern, and
wherein a top surface of the first wiring is not flat and has a cross-sectional shape of a second pattern.
